(19) United States
(12) Patent Application Publication
(10) Pub. No.: US 2008/0044931 A1
(43) Pub. Date: Feb. 21, 2008

(54) Packaging substrate and method of manufacturing the same

(75) Inventors: Ho-Ming Tong, Taipei (TW); Kao-Ming Su, Kaohsiung (TW); Chao-Fu Weng, Tainan (TW); Che-Ya Chou, Kaohsiung (TW); Shin-Hua Chao, Kaohsiung (TW); Teck-Chong Lee, Kaohsiung (TW); Song-Fu Yang, Kaohsiung (TW); Chian-Chi Lin, Tainan (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/646,291

(22) Filed: Dec. 28, 2006

(30) Foreign Application Priority Data
Aug. 21, 2006 (TW) 95130717

(51) Int. Cl. H01L 21/98

(52) U.S. Cl. 438/4; 257/E21.705

(57) ABSTRACT

A packaging substrate and a method of manufacturing the same are provided. The method includes following steps. First, a first substrate including at least one defected packaging unit and several first packaging units is provided. The defected packaging unit and the first packaging units are arranged in an array on the first substrate. Next, the defected packaging unit is removed from the first substrate to correspondingly form at least one opening in the first substrate. Then, a second substrate including at least one second packaging unit is provided. Later, the second packaging unit is separated from the second substrate. The area of the second packaging unit is less than that of the opening. Subsequently, the second packaging unit is disposed in the opening. The edge of the second packaging unit is placed partially against an inner wall of the opening.

This application claims the benefit of Taiwan application Serial No. 95130717, filed Aug. 21, 2006, the subject matter of which is incorporated herein by reference.

### BACKGROUND OF THE INVENTION

1. Field of the Invention

The invention relates in general to a packaging substrate and a method of manufacturing the same, and more particularly to a packaging substrate including all good packaging units and a method of manufacturing the same.

2. Description of the Related Art

Recently, electronic products with light weight and small volume are developed in the industry in order to satisfy the market demand. Also, chips with more functions and more complicated circuits are applied to electronic devices within the limited space. In the general packaging process of semiconductive chips, the semiconductive chips are electrically connected to the substrate through wire-bonding. Electric contacts of the chips are connected to the leads of the substrate, so that inner micro-electronic devices and circuits of the chips are electrically connected to outer circuits. As the chips become more and more complicated, not only the electric contacts of the chips but also the leads of the substrate are increased rapidly. Moreover, because of the popularity of consumer electronic products in the market, the demand for semiconductive chips increases greatly. Therefore, the increment of packaging efficiency and capacity is crucial to all the packaging companies.

Conventionally, strip packaging substrates are used for packaging chips in the packaging process. The strip packaging substrate includes several linearly arranged packaging units. Chips are disposed correspondingly to the packaging units, so that several chips can be packaged at the same time. However, the packaging substrate includes some defected packaging units due to the yield rate. The defected units result in defected package structures, so that the yield rate of the manufacturing process is lowered accordingly. Besides, the defected packaging units are still packaged in the following process. As a result, material is wasted, and the cost is increased. Generally, when the number of the defected units reaches a certain amount, the packaging substrate is no longer usable. Consequently, good packaging units of the same packaging substrate cannot be utilized. The cost of the packaging process is increased, and the packaging efficiency and capacity are lowered.

### SUMMARY OF THE INVENTION

The invention relates to a packaging substrate and a method of manufacturing the same. The packaging substrate includes several array-aligned first packaging units and at least one opening, and at least one second packaging unit disposed in the opening. The edge of the second packaging unit is placed partially against an inner wall of the opening, and the area of the opening is greater than that of the second packaging unit. As a result, the number of chips packaged in the same time is increased. The second packaging unit is positioned in the opening. The stress applied to the first substrate is relieved. Therefore, the packaging process is proceeded smoothly and accurately, and the cost is reduced. Furthermore, the manufacturing efficiency and capacity are increased.

According to one aspect of the invention, a method of manufacturing a packaging substrate is provided. First, a first substrate including at least one defected packaging unit and several first packaging units is provided. The defected packaging unit and the first packaging units are arranged in an array on the first substrate. Next, the defected packaging unit is removed from the first substrate to correspondingly form at least one opening in the first substrate. Then, a second substrate including at least one second packaging unit is provided. Later, the second packaging unit is separated from the second substrate. The area of the second packaging unit is less than that of the opening. Subsequently, the second packaging unit is disposed in the opening. The edge of the second packaging unit is placed partially against an inner wall of the opening.

According to another aspect of the invention, a packaging substrate is provided. The packaging substrate includes several first packaging units, at least one opening and at least one second packaging unit. The opening and the first packaging units are arranged in an array. The second packaging unit is disposed in the opening. The edge of the second packaging unit is placed partially against an inner wall of the opening. The area of the opening is greater than that of the second packaging unit.

The details of the invention will become apparent from the following description of the preferred but non-limiting embodiment. The following description is made with reference to the accompanying drawings.

### BRIEF DESCRIPTION OF THE DRAWINGS

FIG. 1 is a flow chart of a method of manufacturing a packaging substrate according to a preferred embodiment of the invention;

FIG. 2A illustrates a first substrate in a step 101 in FIG. 1;

FIG. 2B illustrates the first substrate in a step 102 in FIG. 1;

FIG. 2C illustrates a second substrate in a step 103 in FIG. 1;

FIG. 2D illustrates the second substrate in a step 104 in FIG. 1;

FIG. 2E illustrates the first substrate in a step 105 in FIG. 1;

FIG. 2F illustrates the first substrate in a step 106 in FIG. 1; and

FIG. 3 illustrates the packaging substrate according to the preferred embodiment of the invention.

### DETAILED DESCRIPTION OF THE INVENTION

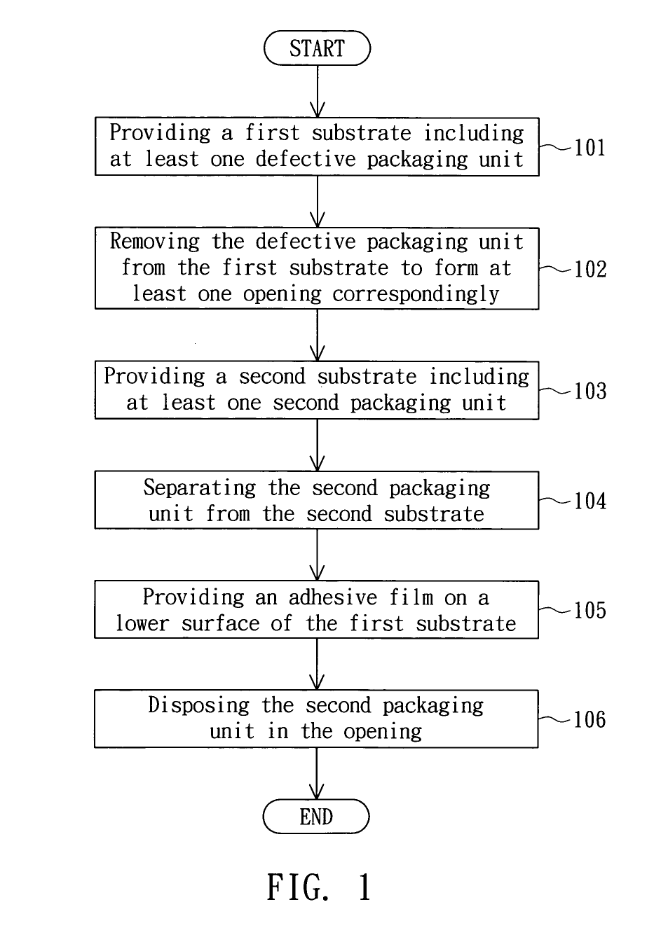

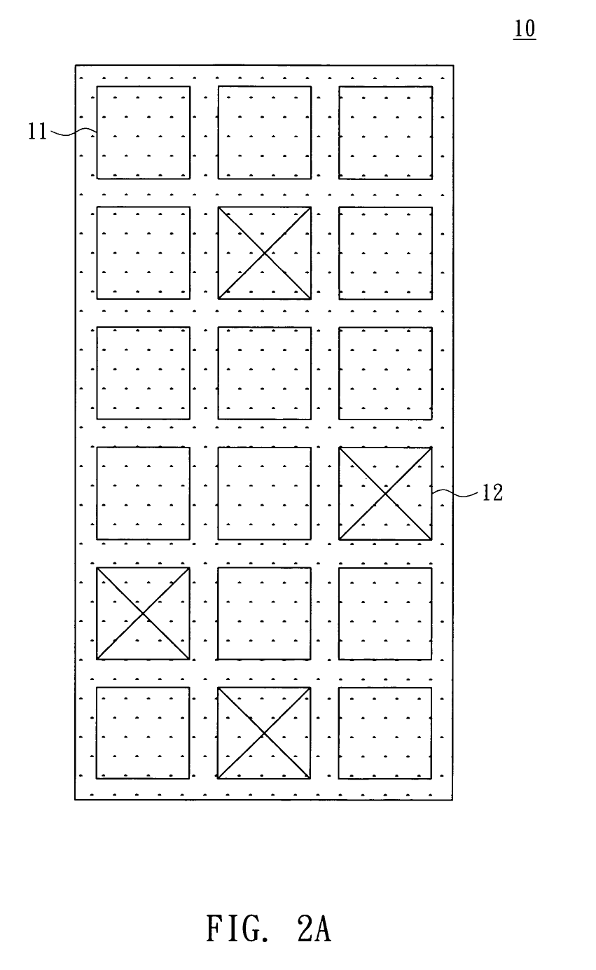

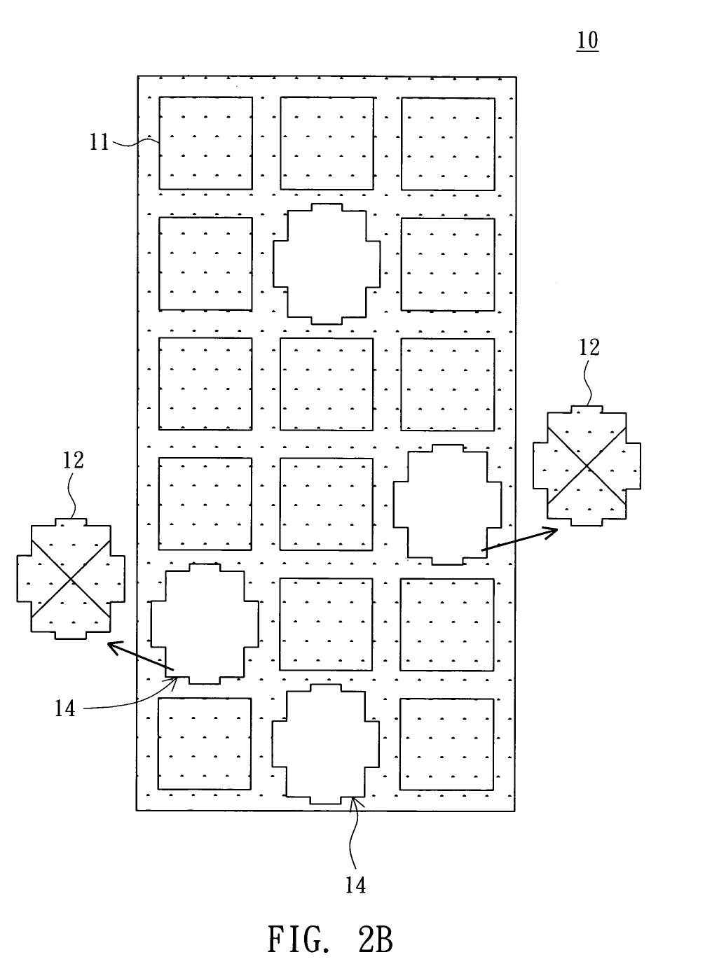

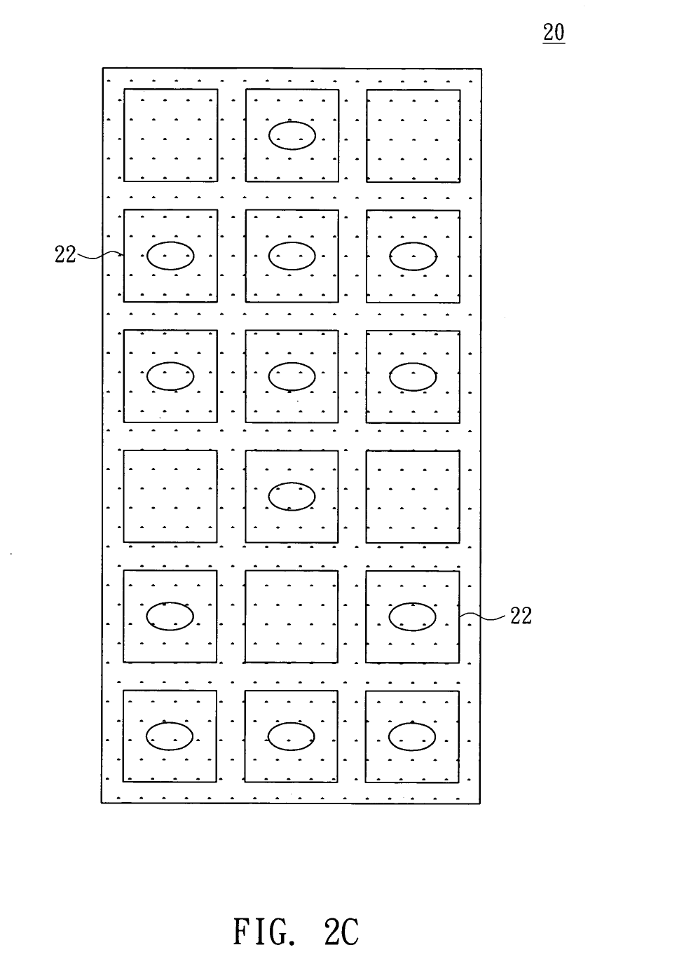

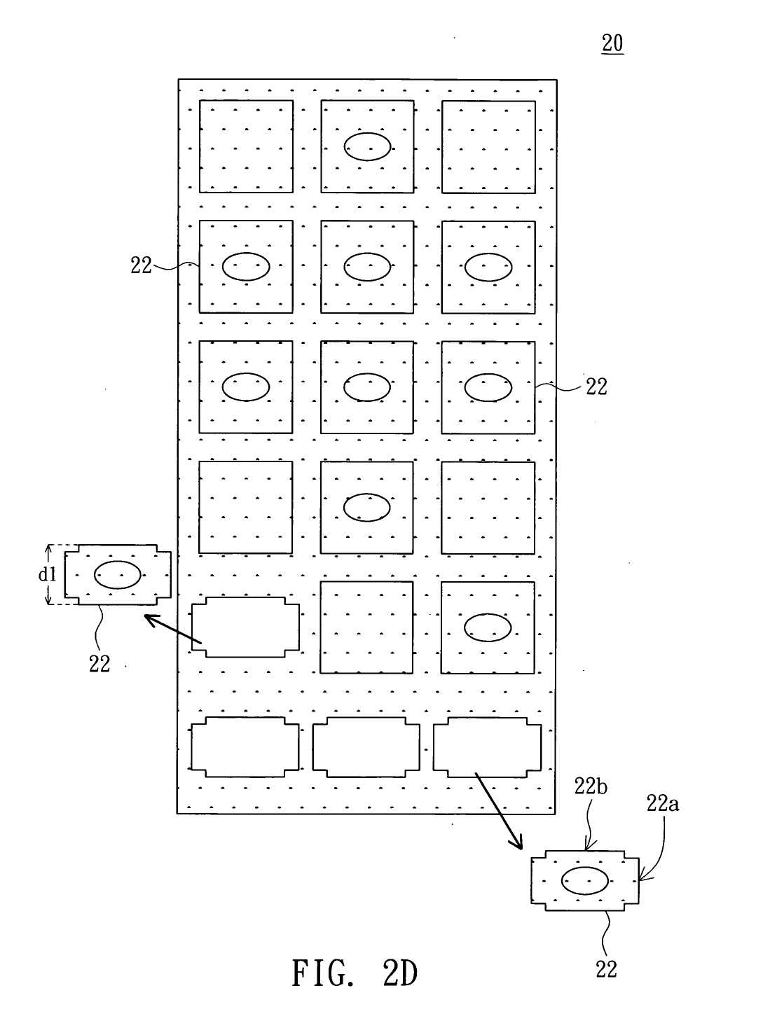

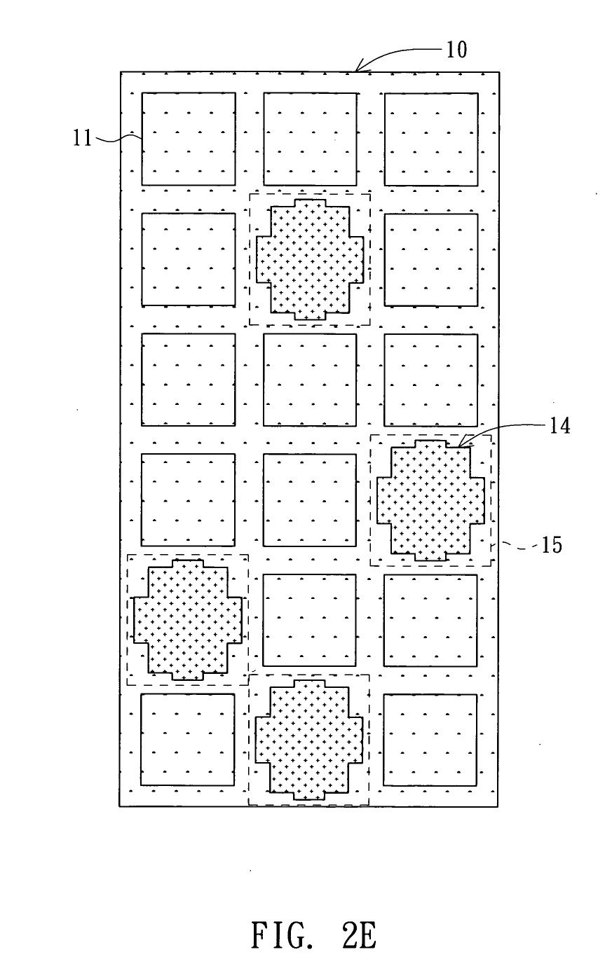

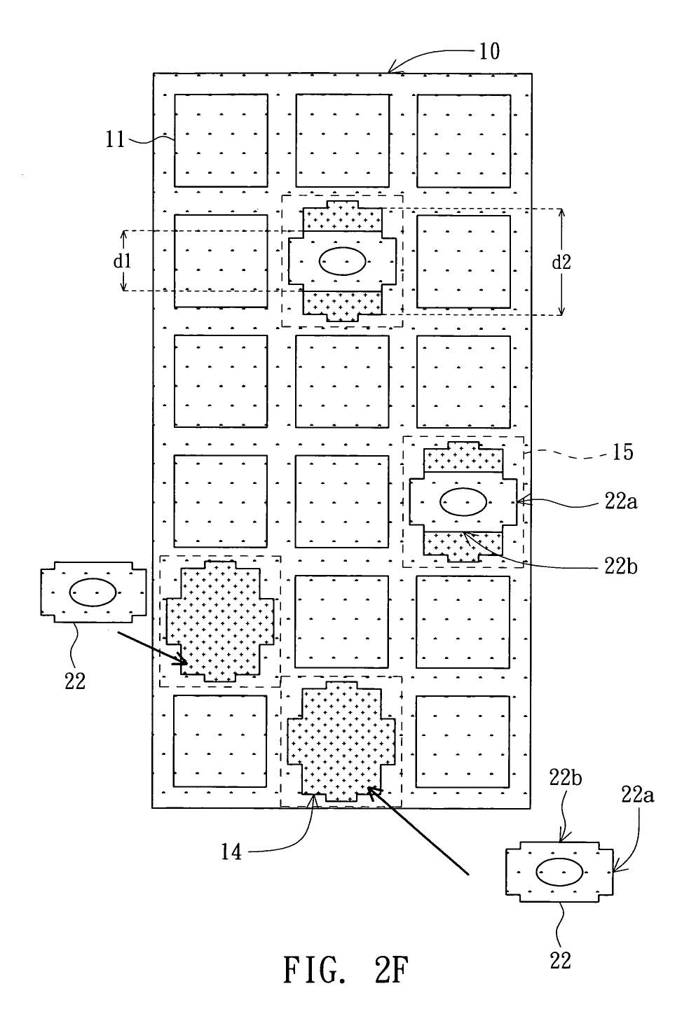

FIG. 1 is a flow chart of a method of manufacturing a packaging substrate according to a preferred embodiment of the invention. FIG. 2A and 2B illustrate a first substrate in a step 101 and a step 102 in FIG. 1 respectively. FIGS. 2C and 2D illustrate a second substrate in a step 103 and a step 104 in FIG. 1 respectively. FIGS. 2E and 2F illustrate the first substrate in a step 105 and a step 106 in FIG. 1 respectively. Please refer to FIG. 1 and FIGS. 2A˜2F at the same time.

First, in the step 101, a first substrate 10 is provided. The first substrate 10 includes at least one defected packaging substrate 12 and several first packaging units 11. The first packaging units 11 are exemplified by ball grid array (BGA) substrates. In the present embodiment, the first substrate 10 includes several defected packaging units 12. The defected packaging units 12 and the first packaging units 11 are arranged on the first substrate 10 in an array. Compared to the conventional strip substrate, the array arrangement increases the number of chips packaged at the same time, so that the packaging efficiency and capacity are increased.

Next, in the step 102, the defected packaging units 12 are removed from the first substrate 10, so that at least one opening 14 is formed in the first substrate 10. In the present embodiment, after the defected packaging units 12 are removed, several openings 14 are formed in the first substrate 10.

Then, in the step 103, a second substrate 20 including at least one second packaging unit 22 is provided. In the present embodiment, the second substrate 20 includes several second packaging units 22. The second packaging units 22 are exemplified by ball grid array (BGA) substrates.

Later, in the step 104, the second packaging units 22 are separated from the second substrate 20. Preferably, the number of the second packaging units 22 separated from the second substrate 20 is the same as that of the openings 14 (as shown in FIG. 2B) of the first substrate 10.

Furthermore, in the step 105, an adhesive film 15 is provided on a lower surface (the reverse side of the paper) of the first substrate 10. In the present embodiment, the adhesive film 15 is disposed on a portion of the lower surface adjacent to the openings 14. The area of the adhesive film 15 is greater than that of the openings 14. A portion of the adhesive film 15 is exposed by the openings 14. The amount of the adhesive film 15 is reduced through this arrangement of the adhesive film 15, so that the cost is decreased.

Subsequently, in the step 106, the second packaging units 22 are disposed in the openings 14. In the step 106, the second packaging units 22 are adhered to the adhesive film 15, so that the second packaging units 22 are disposed in the openings 14. The area of the openings 14 is greater than that of the second packaging units 22. The edge of each second packaging unit 22 is placed partially against an inner wall of each opening 14.

More specifically, each second packaging unit 22 includes a first side 22a and a second side 22b (as shown in FIG. 2D). The second side 22b is substantially perpendicular to the first side 22a. In the present embodiment, the first side 22a and the second side 22b are two substantially perpendicular edges of each second packaging unit 22. The first side 22a has a first width d1. As shown in FIG. 2F, the first side 22a of each second packaging unit 22 is placed against the inner wall of one opening 14. The inner wall that the first side 22a is placed against has a second width d2. The second width d2 is greater than the first width d1. In other words, only the first side 22a of each second packaging unit 22 is placed against the inner wall, so that each second packaging unit 22 is positioned in one opening 14. As a result, in the packaging process, each second packaging unit 22 does not move relatively to the first substrate 10 for keeping the accuracy of the packaging process. Moreover, the second side 22b of each second packaging unit 22 does not contact the inner wall of each opening 14. As a result, when each second packaging unit 22 is disposed in each opening 14, the stress applied to the first substrate 10 is relieved. Therefore, the first substrate 10 is prevented from deforming, so that the packaging process is proceeded smoothly.

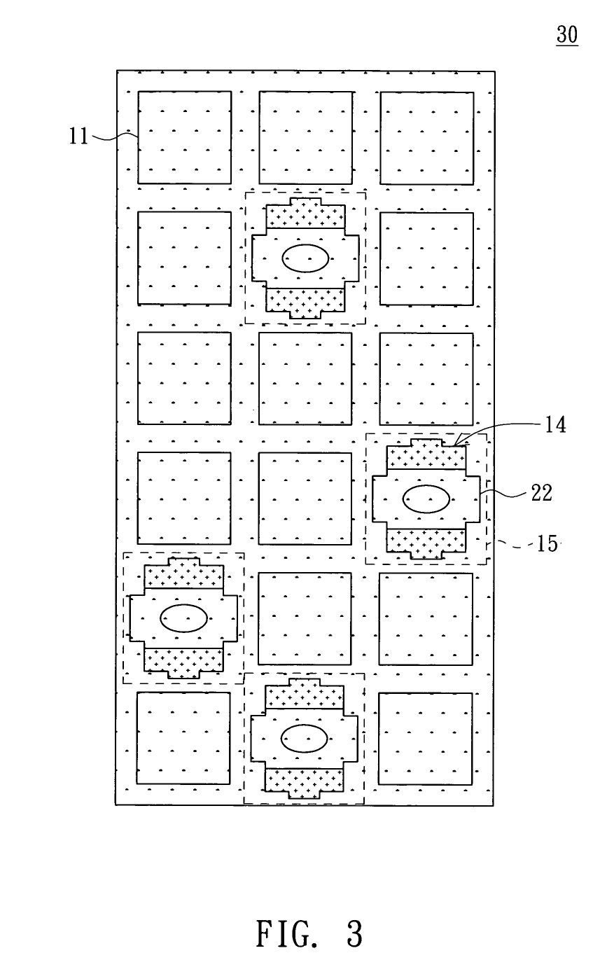

Please referring to FIG. 3, the packaging substrate according to the preferred embodiment of the invention is illustrated in FIG. 3. The second packaging units 22 are adhered to the adhesive film 15, so that the second packaging units 22 are disposed in the openings 14. Then, the packaging substrate 30 of the invention is accomplished.

In the above method of manufacturing the packaging substrate of the invention, the adhesive film 15 is adhered to a portion of the lower surface adjacent to the openings 14 (as shown in FIG. 2E) in the step 105 in FIG. 1. However, the adhesive film 15 can be adhered to the entire lower surface of the substrate 10. As a result, the adhesive film 15 is adhered easily and fast. Also, the manufacturing efficiency of the packaging substrate 30 is increased. Moreover, the manufacturing time of the packaging process is reduced relatively.

In the packaging substrate and the method of manufacturing the same according to the preferred embodiment of the invention, the defected packaging unit of the first substrate is removed, and the opening is formed correspondingly in the first substrate. Then, the good second packaging unit of the second substrate is disposed in the opening, so that all the packaging units on the first substrate are good. The area of the opening is greater than that of the second packaging unit. The second packaging unit is placed partially against the opening. The advantages are as follow.

The first packaging units and the second packaging units are arranged in an array on the packaging substrate, so that the number of the chips packaged in the same time is increased. Also, the manufacturing efficiency and capacity are increased as well.

Only the first side of each second packaging unit is placed against the inner wall of each opening, so that each second packaging unit is positioned in each opening. In the packaging process, each second packaging unit does not move relatively to the first substrate. As a result, the chips are packaged accurately.

The second side of each second packaging unit does not contact the inner wall of each opening. Therefore, the stress applied to the first substrate is relieved when each second packaging unit is disposed in each opening. As a result, the first substrate is prevented from deforming, and the packaging process is proceeded smoothly

Furthermore, because the good first packaging units of the first substrate and the good packaging units of the second substrate can be all used in the packaging process, each good packaging unit is utilized effectively. Therefore, the cost is reduced because good packaging units are not wasted.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing a packaging substrate, the method comprising:
providing a first substrate comprising at least one defected packaging unit and a plurality of first packaging units, the defected packaging unit and first packaging units arranged in an array on the first substrate;
removing the defected packaging unit from the first substrate, at least one opening correspondingly formed in the first substrate;
providing a second substrate comprising at least one second packaging unit;
separating the second packaging unit from the second substrate, the area of the second packaging unit less than the area of the opening; and
disposing the second packaging unit in the opening, the edge of the second packaging unit placed partially against an inner wall of the opening.

2. The method according to claim 1 further comprising:
providing an adhesive film on a lower surface of the first substrate before the step of disposing the second packaging unit, a portion of the adhesive film exposed by the opening.

3. The method according to claim 2, wherein in the step of disposing the second packaging unit, the second packaging unit is adhered to the adhesive film, so that the second packaging unit is disposed in the opening.

4. The method according to claim 2, wherein the adhesive film is disposed on a portion of the lower surface adjacent to the opening, the area of the adhesive film greater than that of the opening.

5. The method according to claim 2, wherein the adhesive film covers the entire lower surface.

6. The method according to claim 1, wherein the second packaging unit has a first side, only the first side of the second packaging unit placed against the inner wall.

7. The method according to claim 6, wherein the first side is placed against a side of the inner wall, the length of the first side less than that of the side of the inner wall.

8. The method according to claim 6, wherein the second packaging unit further has a second side, the second side substantially perpendicular to the first side and not contacting the inner wall.
